(19) United States
(12) Patent Application Publication
(10) Pub. No.: US 2019/0129304 A1
(43) Pub. Date: May 2, 2019

(54) RESIST QUALITY CONTROL METHOD AND METHOD FOR OBTAINING RESIST QUALITY PREDICTION MODEL

(71) Applicant: SHIN-ETSU CHEMICAL CO., LTD., Tokyo (JP)

(72) Inventors: Naoki ARAI, Joetsu-shi (JP); Masayoshi SAGEHASHI, Joetsu-shi (JP); Kazuhiro KATAYAMA, Joetsu-shi (JP)

(73) Assignee: SHIN-ETSU CHEMICAL CO., LTD., Tokyo (JP)

(21) Appl. No.: 16/148,492

(22) Filed: Oct. 1, 2018

(30) Foreign Application Priority Data
Oct. 31, 2017 (JP) 2017-210782

(51) Int. Cl. G03F 7/039; G03F 7/004; G03F 7/20

(52) U.S. Cl. CPC G03F 7/0392; G03F 7/2022; G03F 7/0048

(57) ABSTRACT

An object of the invention is to provide a simple, mechanized analytical approach for resist quality control and early source investigation when a defect occurs. A resist quality control method includes the steps of: (1) pretreating a resist to obtain an analysis sample; (2) subjecting the analysis sample to an instrumental analysis to obtain an analysis result; (3) converting the analysis result into numerical data, followed by a multivariate analysis; and (4) performing a quality control based on an analytical result thus obtained.

### TECHNICAL FIELD

The present invention relates to a resist quality control method and a method for obtaining a resist quality prediction model. More specifically, the present invention relates to a quality control method and a method for obtaining a resist quality prediction model through an instrumental analysis of a constituent substance or an impurity in a resist.

### BACKGROUND ART

Recently, along with advancements toward higher integration and higher speed of LSIs, finer pattern rule has been required. In this situation, resists used to fabricate LSIs are also required to have high stability of quality.

Resists (photoresists) are materials used in a photolithography step which is one involved in the fine circuit pattern formation process for various electronic devices such as semiconductor devices and liquid crystal devices, and each resist contains a photosensitive compound. A resist film formed on a substrate is exposed to light with a circuit pattern drawn in a photomask, so that the resist film has the exposed portion and non-exposed portion. At the exposed portion, a chemical reaction takes place by the photosensitive compound, chancing the solubility to a developer used in the following development step. After a developer soluble portion of the resist film is removed, the circuit pattern of the mask is transferred onto the substrate. By further performing the subsequent steps, a substrate having the pattern drawn thereon can be obtained.

As the state-of-the-art miniaturization technology, approximately 20 nm-node devices are mass-produced by double patterning (SADP) by which films are formed on side walls at both sides of an ArF lithography pattern such that two patterns each having half the line width are formed from the single pattern. A candidate for next-generation 10 nm-node microfabrication technology is SAQP which repeats the SADP twice. However, it is pointed out that this process is very expensive because the formation of side wall films by CVD and processing by dry etching are repeated many times. An extreme ultraviolet ray (EUV) lithography with a wavelength of 13.5 nm is capable of patterning a size around 10 nm by a single light exposure, and the development thereof toward the practical use is about to be accelerated.

While such patterning process technology for line width of several tens of nm or less is being commonly used, quite precise composition control and impurity control are demanded for resist materials. For example, in cases where there are a trace amount of impurities which are not supposed to be present and where the metal impurity content is high, defects are introduced during the patterning process. For this reason, the importance of strengthening these controls has been emphasized.

The contamination with a trace amount of impurities is conceivably caused by insufficient cleanliness control in the production facility, and sometimes originated from resist-constituent raw materials such as a base polymer, a photo acid generator (PAG), and a solvent. Hence, when the resist materials are produced, facility environments and production process conditions are quite strictly controlled at levels exceeding the control in producing usual chemical products, and each raw material is controlled in every lot in such a manner as to minimize variations in qualities including purity.

Conventional resist quality control methods utilize the photolithography step. In the first method, a resist solution is prepared and then applied to a substrate, a circuit pattern drawn in a photomask is transferred to the resist film, and subsequently whether a desired line width is obtained or not is inspected using a scanning electron microscope or the like to thus perform a line width control. Further, in the second method, a resist solution is prepared and then applied to a substrate, and an undesirable matter is inspected using a wafer surface inspection apparatus or the like to thus perform an undesirable matter control based on a trace amount of impurities, for example. In the third method, a resist solution is prepared and then applied to a substrate, a circuit pattern drawn in a photomask is transferred to the resist film, and subsequently a minute pattern defect is inspected based on a trace amount of impurities, for example, using a bright-field inspection apparatus or the like to thus perform a defect density control on the substrate.

However, the methods as described above include the step of applying a resist to a substrate but not an approach of directly analyzing the produced resist composition. Accordingly, the methods do not always reflect the quality of the resist itself. In addition, it cannot be said that these approaches are simple, either.

Meanwhile, recently, analysis called multivariate analysis or chemometrics has been actively used which employs a method of applying mathematical or statistical approaches so as to maximize the amount of chemical information acquired from chemical data such as spectra and chromatograms obtained by various measurements. For resist polymers also, approaches employing multivariate analyses for property evaluation have been proposed (Patent Document 1).

However, the target of the approaches described in Patent Document 1 is limited to resist polymers. The approaches alone cannot control the quality of produced resist compositions.

### CITATION LIST

### Patent Literature

Patent Document 1: Japanese Patent No. 5811848

### SUMMARY OF THE INVENTION

### Technical Problem

The present invention has been made to solve the above problems. An object of the present invention is to provide a simple, mechanized analytical approach for resist quality control and early source investigation when a defect occurs.

### Solution to Problem

To achieve the above object, the present invention provides a resist quality control method comprising the steps of:

(1) pretreating a resist to obtain an analysis sample;

(2) subjecting the analysis sample to an instrumental analysis to obtain an analysis result;

(3) converting the analysis result into numerical data, followed by a multivariate analysis; and

(4) performing a quality control based on an analytical result thus obtained.

This resist quality control method directly analyzes and evaluates a resist to control the quality, thus enabling a simple, mechanized analytical approach for resist quality control and early source investigation when a defect occurs.

Moreover, the multivariate analysis is preferably a principal component analysis (PCA).

Such a multivariate analysis is capable of specifically finding out a slight difference in a defect lot, which may be left unnoticed by glancing at an analysis result (chart), and enables a superior analytical approach.

Further, the instrumental analysis is preferably a nuclear magnetic resonance analysis.

The analysis result obtained by such an instrumental analysis measurement presents abundant structural information, simplifies specimen preparation, and shortens the analysis time. Additionally, the analysis result has a non-selective characteristic. Thus, these enable a superior analytical approach.

Furthermore, the pretreatment may be dissolving the resist into a solvent.

Such a pretreatment is simple and can also be suitably used in, for example, a nuclear magnetic resonance analysis and the like.

In the resist quality control method, a peak derived from any one of a resist polymer, an acid generator, and a basic compound, which is included in the analysis result, is preferably used as an indicator.

Such a resist quality control method enables a more highly precise analytical approach.

In addition, the present invention provides a method for obtaining a resist quality prediction model, comprising the steps of:

(1) pretreating a plurality of resists whose qualities are known to obtain individual analysis samples;

(2) subjecting the individual analysis samples to an instrumental analysis to obtain individual analysis results; and

(3) converting a relation between the individual analysis results and the qualities into numerical data, followed by a multivariate analysis.

This method for obtaining a resist quality prediction model can provide a quality prediction model advantageous in resist quality control.

In this case, a preferable resist quality control method comprises the steps of:

(1) pretreating a resist to obtain an analysis sample;

(2) subjecting the analysis sample to an instrumental analysis to obtain an analysis result;

(3) converting the analysis result into numerical data, followed by a multivariate analysis; and

(4) checking an analytical result thus obtained with a quality prediction model obtained as described above.

This resist quality control method enables a further simple and highly precise quality control method.

### Advantageous Effects of Invention

As has been described above, the inventive resist quality control method can provide a simple, accurate, and mechanized analytical approach for resist quality control and early source investigation when a defect occurs. Moreover, the present invention makes it possible to simplify the is quality control of a resist itself, which has been difficult to perform by conventional approaches, and can discover a defect resist without actually applying a resist to a substrate for an exposure evaluation test. Accordingly, the present invention can contribute to the realization of highly precise, efficient, quick, and simple quality control. Further, the inventive method for obtaining a quality prediction model can provide a quality prediction model advantageous in resist quality control.

### BRIEF DESCRIPTION OF DRAWINGS

FIG. 1 is a scatter diagram of PC1 and PAG ratio, where Composition 1 serves as a reference resist, the horizontal axis represents the PAG-2/PAG-1 ratio of Compositions 2 to 4, and the vertical axis represents the PC1 value obtained by the PCA analysis on 1H-NMR measurement charts of Compositions 1 to 4;

FIG. 2 shows a 1H-NMR chart of Composition 1 (the vertical axis: peak intensity, arbitrary unit) (A), and a loading chart based on the PCA analysis on the 1H-NMR measurement charts of Compositions 1 to 4 (the vertical axis: peak intensity, arbitrary unit) (B);

FIG. 3 shows scatter diagrams of PC1 and various evaluation results of Compositions 1 to 4, where the horizontal axis represents the PC1 value obtained by the PCA analysis on the 1H-NMR measurement charts of Compositions 1 to 4, and the vertical axis represents the various evaluation results;

FIG. 4 is a scatter diagram of PC1 and the amount of PAG added, where Composition 1 serves as a reference resist, the horizontal axis represents the amount of PAG-1 added to Compositions 5 to 8, and the vertical axis represents the PC1 value obtained by the PCA analysis on 1H-NMR measurement charts of Compositions 5 to 8;

FIG. 5 is a loading chart based on the PCA analysis on the 1H-NMR measurement charts of Compositions 1 and 5 to 8 (the vertical axis: peak intensity, arbitrary unit); and

FIG. 6 shows scatter diagrams of PC1 and various evaluation results of Compositions 1 and 5 to 8, where the horizontal axis represents the PC1 value obtained by the PCA analysis on the 1H-NMR measurement charts of Compositions 1 and 5 to 8, and the vertical axis represents the various evaluation results.

### DESCRIPTION OF EMBODIMENTS

As described above, it has been desired to develop an accurate, simple, and mechanized analytical approach for resist quality control and early source investigation when a defect occurs.

The present inventors have earnestly studied to achieve the above object and consequently found that favorable correlations are observed between the PCA analytical results on resist compositions and actual evaluation test results, so that a defect lot can be discovered by estimating an evaluation result by a multivariate analysis without conducting an exposure evaluation test on the resist. This finding has led to the completion of the present invention.

Specifically, the present invention is a resist quality control method comprising the steps of:

(1) pretreating a resist to obtain analysis sample;

(2) subjecting the analysis sample to an instrumental analysis to obtain an analysis result;

(3) converting the analysis result into numerical data, followed by a multivariate analysis; and

(4) performing a quality control based on an analytical result thus obtained.

Hereinafter, the present invention will be described in detail. However, the present invention is not limited thereto.

### [Step (1)]

Step (1) is a step of pretreating a resist to obtain an analysis sample.

In the present invention, a resist can be subjected to various instrumental analyses after appropriately pretreated (measurement specimen preparation) according to the type of the instrumental analysis to be employed. The pretreatment can be, for example, dissolving the resist into a solvent. In a case where NMR is employed as the instrumental analysis, the solvent for dissolving the resist composition includes deuterated dimethyl sulfoxide (DMSO-d6), deuterated chloroform, deuterated acetone, and the like, and DMSO-d6 is preferable.

### [Step (2)]

Step (2) is a step of subjecting the analysis sample to an instrumental analysis to obtain an analysis result.

The resist sample pretreated as described above is subjected to any instrumental analysis, so that an analysis result is obtained. The analysis result thus obtained may be a fingerprint of the resist sample. This fingerprint is converted into numerical data which is subjected to a multivariate analysis. The result obtained by the instrumental analysis includes the retention time and spectrum data such as signal intensity (or ionic strength).

In the present invention, the instrumental analysis refers to analysis and measurement means using an analytical instrument, and includes nuclear magnetic resonance analysis (NMR), gas chromatography (GC), liquid chromatography (LC), mass spectrometry (MS), infrared spectrometry (IR), near-infrared spectrometry (NIR), and the like. These instrumental analyses may be combined. Examples of the combination include GC/MS, LC/MS, and the like. The apparatus used in these instrumental analyses is not particularly limited and may be a generally-used apparatus, as long as it enables measurements of resist constituent components (polymer, acid generator (PAG), basic compound, other additives). Moreover, the measurement conditions can be appropriately set to be suitable for the measurements of these substances. In the present invention, NMR is suitably adopted in views of presenting abundant structural information, simplifying specimen preparation, shortening the analysis time, and having a non-selective characteristic. Particularly, 1H-NMR is preferable from the viewpoints of the measurement sensitivity and the measurement time.

### [Step (3)]

Step (3) is a step of converting the analysis result into numerical data, followed by a multivariate analysis.

In the multivariate analysis, various analysis tools are adopted for the analysis of the instrumental analysis data. Examples of the various analysis tools include those for PCA (principal component analysis), HCA (hierarchical cluster analysis), PLS regression analysis (Projection to Latent Structure), discriminate analysis, and the like. A large number of these analysis tools are commercially available as software, and any of these may be obtained. Such commercially-available tools are generally provided with operation manuals so that a multivariate analysis can be performed without difficult mathematical and statistical knowledge.

The multivariate analysis may be performed not on all the obtained data but data selected within a certain range. For example, in the case of 1H-NMR analysis, the analysis may be performed using data from which the solvent peak of the resist is removed.

Moreover, the multivariate analysis is preferably a principal component analysis (PCA). In the principal component analysis (PCA), Quantitative data having a large number of variables, such as an NMR spectrum of a mixture, is reduced to a smaller number of uncorrelated synthetic variables (principal component scores PC1, PC2, for the analysis. When a large number of samples are categorized into multiple groups, a substance which influences a difference among samples is examined, or the overall distribution trend of data is grasped, the principal component analysis is normally utilized. This makes it possible to specifically find out a slight difference in a defect lot, which may be left unnoticed by glancing at an analysis result (chart).

Further, another important indicator obtained from the multivariate analysis is a contribution ratio which indicates in what proportion a component accounts for a variation in data. For example, suppose a case where the contribution ratio of the first principal component PC1 is 80%, the contribution ratio of the second principal component PC2 is 10%, the contribution ratio of the third principal component PC3 is 5%, and so forth. In this case, it can be said that the first principal component PC1 alone accounts for most of the variations in the overall data. Thus, this contribution ratio is useful in determining how many principal components should be verified.

As the procedure of performing the PCA analysis on an NMR measurement result, first, a chart obtained by the measurement is subjected to divisional integration to prepare a peak matrix. This peak matrix is subjected to the principal component analysis, so that scores of principal components of each sample or the loading of each principal component can be calculated.

### [Step (4)]

Step (4) is a step of performing a quality control based on an analytical result thus obtained.

For example, in a case where the same type of resists across multiple lots are measured by the instrumental analysis and subjected to the multivariate analysis, if defect lots having different constituent component ratios are mixed in the multiple lots, the analytical values (analytical results) of the defect lots exhibit different values from those of a group consisting of normal lots, and can be selected.

Meanwhile, in the present invention, Step (4) may be a step of checking the obtained analytical result with a quality prediction model.

In this case, the quality prediction model can be obtained by a method for obtaining a resist quality prediction model, which includes the steps of:

(1) pretreating a plurality of resists whose qualities are known to obtain individual analysis samples;

(2) subjecting the individual analysis samples to an instrumental analysis to obtain individual analysis results; and

(3) converting a relation between the individual analysis results and the qualities into numerical data, followed by a multivariate analysis.

As described above, the quality prediction model can be easily obtained by the above-described method for obtaining a quality prediction model. Further, checking the analytical result on the multivariate analysis with the quality prediction model thus obtained enables a resist quality control method which is simple and highly precise.

### EXAMPLES

Hereinafter, the present invention will be described specifically by way of Examples and Comparative Example. However, the present invention is not limited thereto.

### Preparation of Resist Materials

### [Preparation of Compositions 1 to 8]

Resist raw materials of compositions shown in Table 1 were mixed, and filtered through a 0.2-μm TEFLON (registered trademark) filter. Thereby, resist materials R-01 to R-08 were prepared. Note that the resin, photo acid generators, water-repellent polymer, sensitivity modifier, and solvents in Table 1 are as follows.

Resin: Polymer 1

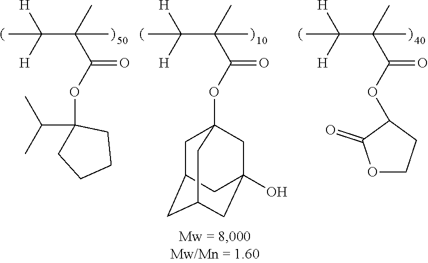

Photo Acid Generator: PAG-1

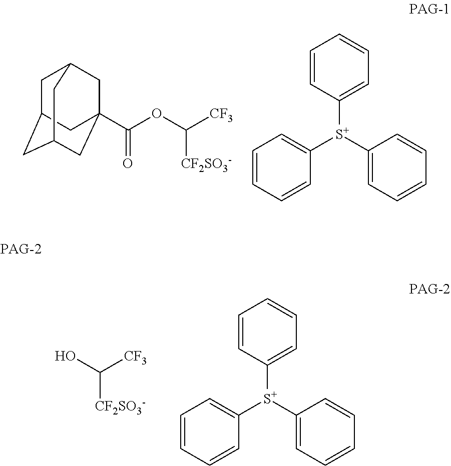

Sensitivity Modifier: AQ-1

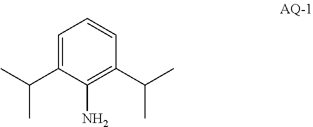

Water-Repellent Polymer: SF-1

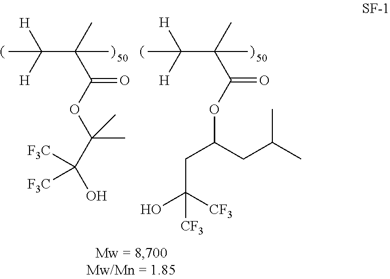

Solvents

PGMEA: propylene glycol monomethyl ether acetate

GBL: γ-butyrolactone

TABLE 1

| | | | | | Water- | |
|---|---|---|---|---|---|---|
| | | | Photo acid | Sensitivity | repellent | |
| | Resist | Resin | generator | modifier | polymer | Solvent |
| | material | (part by mass) | (part by mass) | (part by mass) | (part by mass) | (part by mass) |
| Composition 1 | R-01 | Polymer 1 (100) | PAG-1 (12.6) | AQ-1 (0.5) | SF-1 (1.5) | PGMEA(1440) |
| | | | | | | GBL(160) |
| Composition 2 | R-02 | Polymer 1 (100) | PAG-1 (8.8) | AQ-1 (0.5) | SF-1 (1.5) | PGMEA(1440) |
| | | | PAG-2 (3.8) | | | GBL(160) |
| Composition 3 | R-03 | Polymer 1 (100) | PAG-1 (6.3) | AQ-1 (0.5) | SF-1 (1.5) | PGMEA(1440) |
| | | | PAG-2 (6.3) | | | GBL(160) |
| Composition 4 | R-04 | Polymer 1 (100) | PAG-1 (2.5) | AQ-1 (0.5) | SF-1 (1.5) | PGMEA(1440) |
| | | | PAG-2 (10.1) | | | GBL(160) |
| Composition 5 | R-05 | Polymer 1 (100) | PAG-1 (10.1) | AQ-1 (0.5) | SF-1 (1.5) | PGMEA(1440) |
| | | | | | | GBL(160) |
| Composition 6 | R-06 | Polymer 1 (100) | PAG-1 (15.2) | AQ-1 (0.5) | SF-1 (1.5) | PGMEA(1440) |
| | | | | | | GBL(160) |
| Composition 7 | R-07 | Polymer 1 (100) | PAG-1 (7.6) | AQ-1 (0.5) | SF-1 (1.5) | PGMEA(1440) |
| | | | | | | GBL(160) |
| Composition 8 | R-08 | Polymer 1 (100) | PAG-1 (17.6) | AQ-1 (0.5) | SF-1 (1.5) | PGMEA(1440) |
| | | | | | | GBL(160) |

### [Exposure Evaluation Test]

Each resist composition prepared from the composition shown in Table 1 was applied onto a substrate by spin coating, the substrate having been prepared by forming an organic antireflective film from ARC29A (manufactured by Nissan Chemical Industries, Ltd.) to have a film thickness of 78 nm on a silicon wafer. The resultant was baked with a hot plate at 100° C. for 60 seconds to obtain a resist film having a thickness of 100 nm. Using an ArF excimer laser scanner (NSR-S307E manufactured by Nikon Corporation, NA=0.85, σ: 0.93/0.74, Annular illumination, 6% halftone phase shift mask), this resist film was exposed to light with an isolated pattern having a space width of 90 nm and a pitch of 1,650 nm and with line-and-space patterns (LS patterns) having the following sizes on the wafer: a space width of 90 nm and a pitch of 180 nm; a space width of 80 nm and a pitch of 160 nm; and a space width of 70 nm and a pitch of 140 nm. In this event, the exposure was performed while changing the exposure dose and focus (exposure dose pitch: 1 mJ/cm², focus pitch: 0.025 μm). After the exposure, the resultant was subjected to PEB at a temperature shown in Table 2 for 60 seconds, puddle developed with a 2.38 mass % TMAH aqueous solution for 10 seconds, rinsed with pure water, and spin dried. Thus, a positive type pattern was obtained. After the development, the LS patterns and isolated pattern were observed with TD-SEM (S-9380 manufactured by Hitachi High-Technologies Corporation).

### <Sensitivity Evaluation>

As the sensitivity evaluation, an optimum exposure dose Eₒₚ (mJ/cm²) at which an LS pattern having a space width of 90 nm and a pitch of 180 nm was obtained was determined. Table 2 shows the result. The smaller the value, the higher the sensitivity.

### <Exposure Latitude (EL) Evaluation>

As the exposure latitude evaluation, an exposure latitude (unit: %) was determned according to the following equation from the exposure doses at which the space width in the LS pattern was formed within a range of 90 nm±10% (81 to 99 nm). Table 2 shows the result.

Exposure latitude (%)=(|E₁−E₂|/Eₒₚ)×100

E₁: optimum exposure dose providing an LS pattern having a space width of 81 nm and a pitch of 180 nm

E₂: optimum exposure dose providing an LS pattern having a space width of 99 nm and a pitch of 180 nm

Eₒₚ: optimum exposure dose providing an LS pattern having a space width of 90 nm and a pitch of 180 nm

### <Line Width Roughness (LWR) Evaluation>

The size of the LS pattern obtained by the irradiation at the optimum exposure dose in the sensitivity evaluation was measured at ten positions in a longitudinal direction of the space width. The standard deviation (σ) was determined from the result. The triple value (3σ) of the standard deviation (σ) was regarded as the LWR. Table 2 shows the result. The smaller the value, the smaller the roughness and the more uniform the space width of the obtained pattern.

### <Depth-of-Focus (DOF) Evaluation>

As the depth-of-focus evaluation, a focus range was determined from the focuses at which the space width in the isolated pattern was formed within a range of 90 nm±10% (81 to 99 nm). Table 2 shows the result. The larger the value, the greater the depth of focus.

### <Resolution Evaluation>

A pattern size at which an LS pattern having a space width of 70 to 90 cm (pitch: 140 to 180 nm) was able to resolve was regarded as the resolution Table 2 shows the result. The smaller the value, the more excellent the resolution.

TABLE 2

| | | PEB | | | | | |
|---|---|---|---|---|---|---|---|
| | | temper- | | | | | |
| | Resist | ature | Eₒₚ | EL | LWR | DOF | Reso- |
| | material | (° C.) | (mJ/cm²) | (%) | (nm) | (μm) | lution(nm) |
| Compo- | R-01 | 100 | 45 | 18 | 4.0 | 0.15 | 70 |
| sition 1 | | | | | | | |
| Compo- | R-02 | 100 | 43 | 16 | 4.2 | 0.17 | 80 |
| sition 2 | | | | | | | |
| Compo- | R-03 | 100 | 34 | 13 | 4.5 | 0.19 | 80 |
| sition 3 | | | | | | | |
| Compo- | R-04 | 100 | 23 | 11 | 4.6 | 0.20 | 80 |
| sition 4 | | | | | | | |
| Compo- | R-05 | 100 | 53 | 20 | 4.1 | 0.13 | 80 |
| sition 5 | | | | | | | |
| Compo- | R-06 | 100 | 40 | 17 | 3.8 | 0.16 | 70 |
| sition 6 | | | | | | | |
| Compo- | R-07 | 100 | 58 | 21 | 4.2 | 0.11 | 90 |
| sition 7 | | | | | | | |
| Compo- | R-08 | 100 | 33 | 16 | 3.7 | 0.17 | 70 |
| sition 8 | | | | | | | |

### Example 1

### [Preparation and Analyses of 1H-NMR Analysis Samples]

The prepared resist composition, 0.2 ml, was dissolved into 0.36 ml of deuterated dimethyl sulfoxide (DMSO-d6) to prepare a measurement sample (analysis sample). The obtained measurement sample was measured by 1H-NMR. In this Example, a spectrometer ECA-600 manufactured by JEOL, Ltd. was used, and a spectrum was obtained with a 5-mmφ multinuclear probe. DMSO-d6 was used as the internal lock signal and chemical shift internal standard. As the measurement conditions, the single pulse method was employed, the pulse angle was 45°, the number of scans was 16, and the number of data points was 32 K, so that the data were incorporated.

The phase and baseline corrections were performed on the spectrum obtained by the 1H-NMR measurement with ALICE2 for Metabolome (JEOL RESONANCE), and the PCA analysis was performed. The analytical range covered a range of −1 to 10 ppm, and the spectrum was integrated at intervals of 0.04 ppm and normalized after the peaks of the solvent and the deuterated solvent were removed. The NMR peaks were assigned by individually measuring each material by 1H-NMR before the resist composition formulation and comparing the spectra.

### [PGA Analytical Results on 1H-NMR Measurement Results of Compositions 1 to 4]

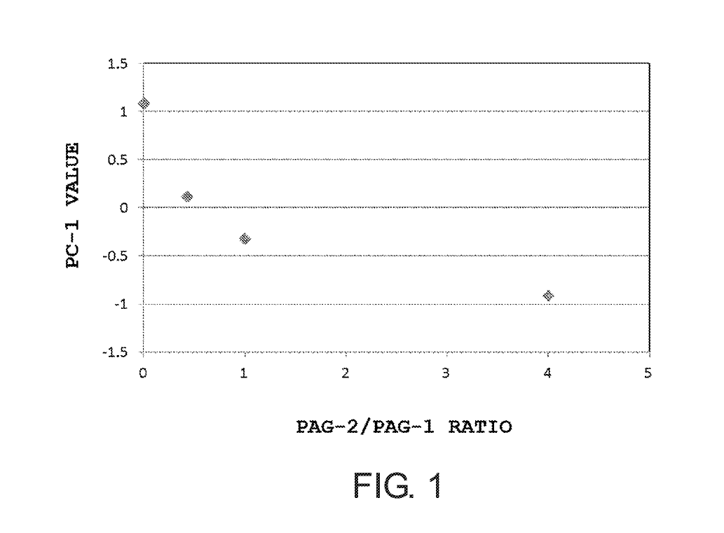

FIG. 1 shows a scatter diagram of the PC1 values obtained by the PCA analysis on the 1H-NMR measurement results of Compositions 1 to 4 and the PAG-2/PAG-1 ratio of each composition. In this event, the contribution ratio of PC1 was 83.9%. In comparison with the resist of Composition 1 containing no PAG-2, as the proportion of PAG-2 increased, the PC1 value was decreased. Thus, a favorable correlation was found between the PAG-2/PAG-1 and the PC1 value

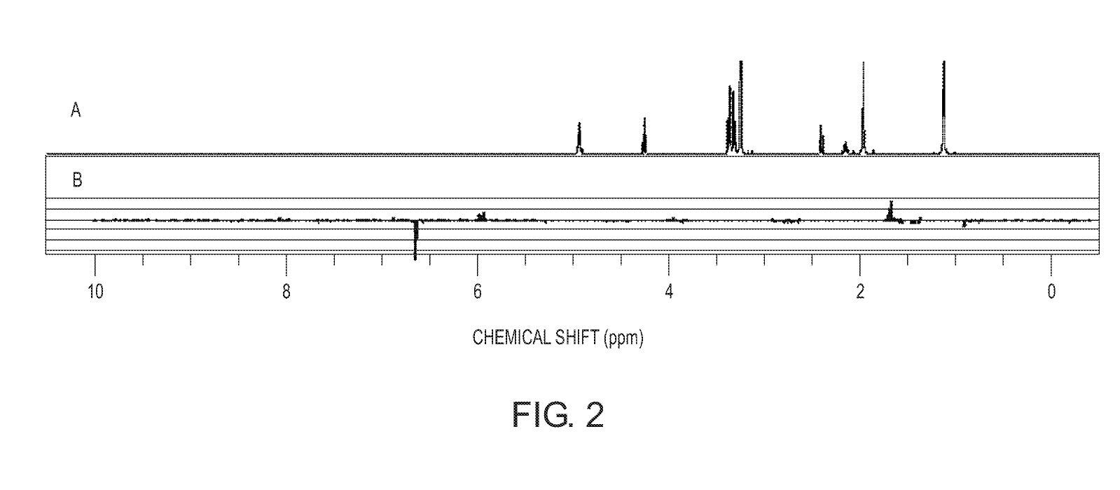

B in FIG. 2 shows a loading chart obtained by the PCA analysis on the 1H-NMR measurement results of the resist compositions of Compositions 1 to 4. From B in FIG. 2, the result was obtained which showed that there were differences at 1.7 ppm, 6.0 ppm, and 6.6 ppm. The comparison result with the standard sample of each constituent component of the resist compositions verified that these chemical shifts were assigned to PAG-1 and PAG-2. From these results, the PCA analysis showed that the variation factor of the PC1 values of Compositions 1 to 4 was attributable to the difference in the ratio of PAG-1 and PAG-2 in the resist compositions.

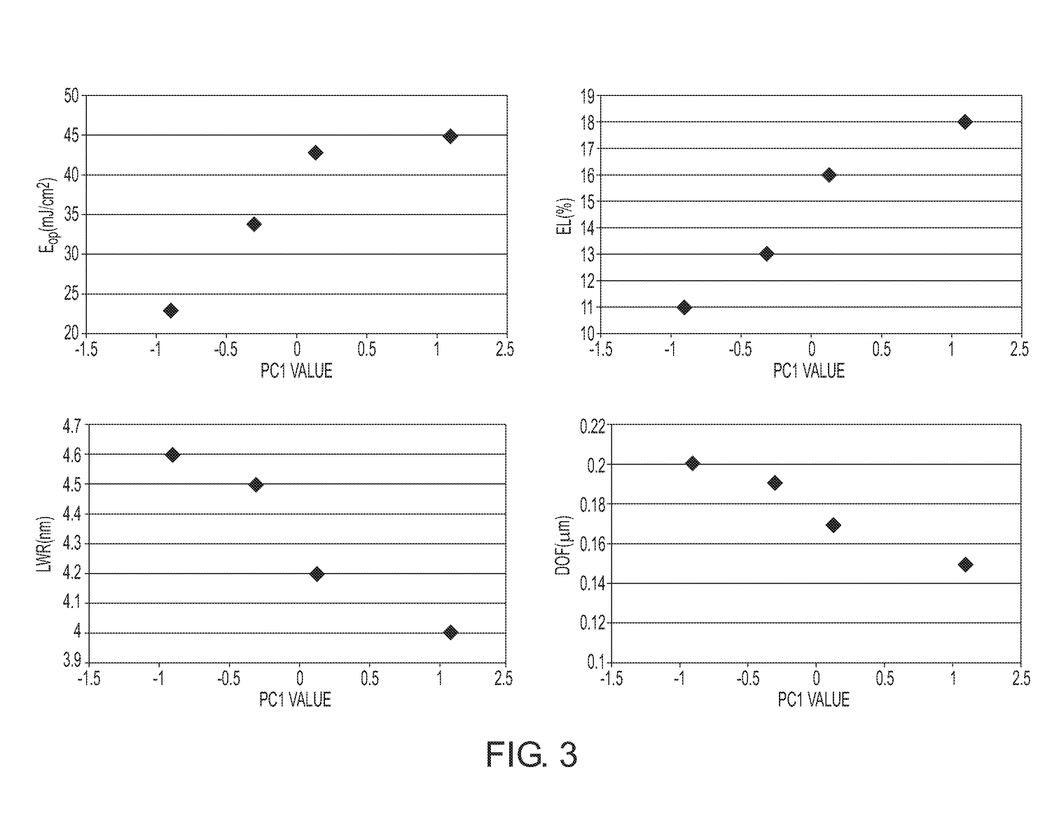

FIG. 3 shows scatter diagrams of the PC1 values obtained by the PCA analysis on the 1H-NMR measurement results of Compositions 1 to 4 and each evaluation result of Compositions 1 to 4. Correlations were found between the PC1 value and each evaluation result of sensitivity, exposure latitude, line width roughness, and depth of focus. Normally, the resist sensitivity is unknown if an exposure evaluation test is not conducted. However, without conducting an exposure evaluation test as described above, the multivariate analysis enables the estimation of the resist sensitivity, the discovery of the defect lot, and also the identification of the defect source. It has been Impossible to reveal the source of a sensitivity variation so far by the result of an exposure evaluation test alone. In contrast, employing the multivariate analysis makes it possible to estimate the sensitivity variation and identify the variation factor.

### Comparative Example 1

A in FIG. 2 shows a 1H-NMR chart of Composition 1. Only the peak of the solvent constituting the resist composition can be confirmed from A in FIG. 2. It is quite difficult to find out differences in the constituent components of the resist composition from this chart.

### Example 2

### [PCA Analytical Results on 1H-NMR Measurement Results of Compositions 1 and 5 to 8]

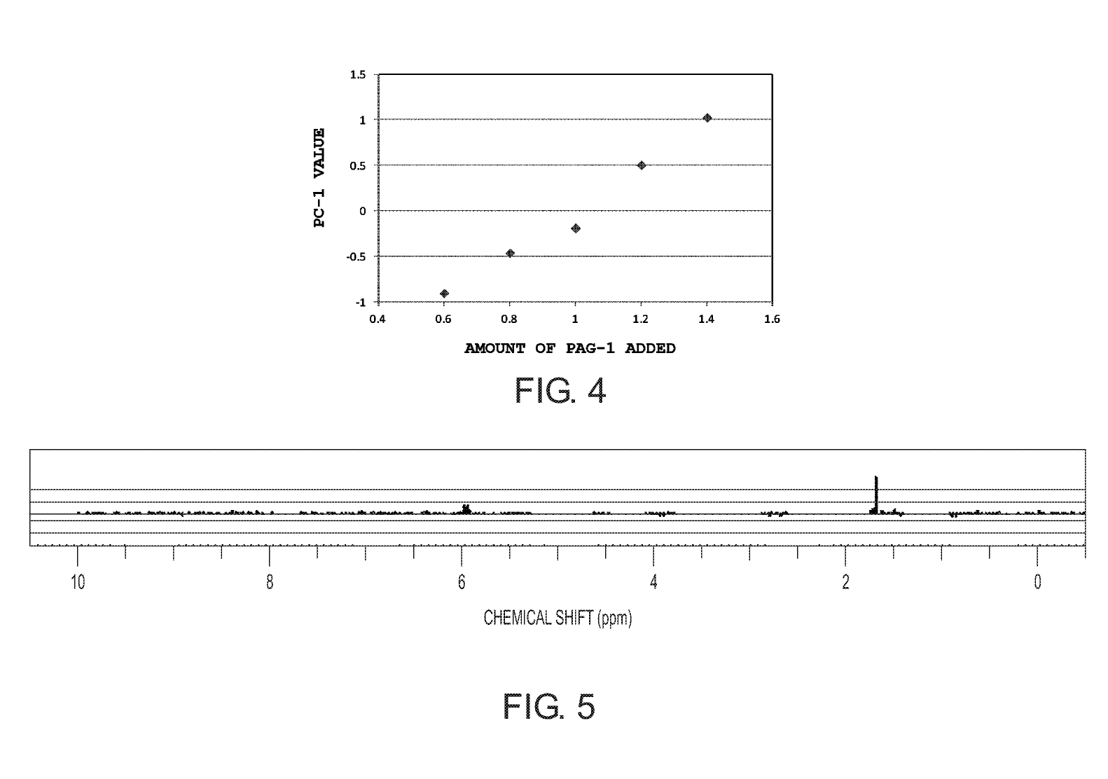

FIG. 4 shows a scatter diagram of the PC1 values obtained by the PCA analysis on the 1H-NMR measurement results of Compositions 1 and 5 to 8 and the amount of PAG-1 added to each composition. In this event, the contribution ratio of PC1 was 81.5%. In comparison with Composition 1, the PC1 value was also increased or decreased in synchronism with an increase or a decrease in the amount of PAG-1 added. A favorable correlation was found between the amount of PAG-1 added and the PC1 value.

FIG. 5 shows a loading chart obtained by the PCA analysis on the 1H-NMR measurement results of Compositions 1 and 5 to 8. From the chart, the result was obtained which showed that there were differences at 1.7 ppm and 6.0 ppm. As in the result of B in FIG. 2, the comparison result with the standard samples verified that these chemical shifts were assigned to PAG-1. From these results, the PCA analysis showed that the variation factor of the PC1 values of Compositions 1 and 5 to 8 was attributable to the difference in the amount of PAG-1 added into the resist compositions.

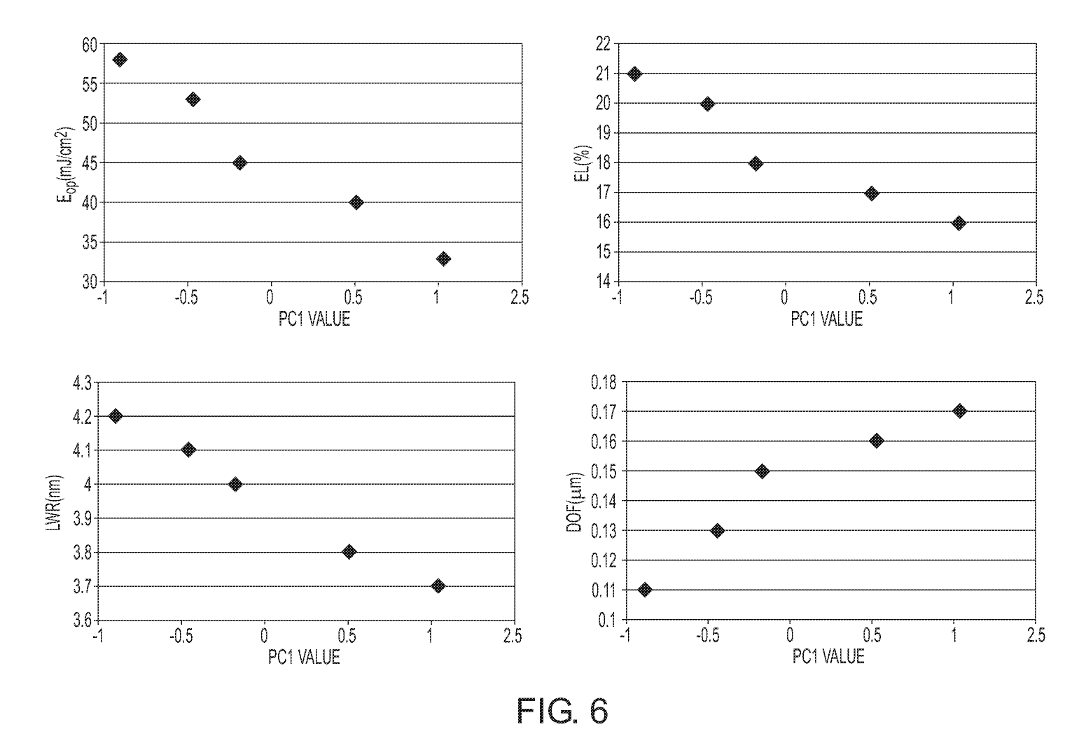

FIG. 6 shows scatter diagrams of the PC1 values obtained by the PCA analysis on the 1H-NMR measurement results of Compositions 1 and 5 to 8 and each evaluation result of Compositions 1 and 5 to 8. As in FIG. 3, correlations were found between the PC1 value and each evaluation result of sensitivity, exposure latitude, line width roughness, and depth of focus.

From the above evaluation results, favorable correlations are found between the PCA analytical results on the resist compositions and the actual evaluation test results. From these, although a resist sensitivity is normally unknown if an exposure evaluation test is not conducted, the multivariate analysis makes it possible to estimate the resist sensitivity, discover a defect lot, and also identify a defect source, without conducting an exposure evaluation test. As described above, the present invention has revealed that it is possible to provide a simple, mechanized analytical approach for resist quality control and early source investigation when a defect occurs.

It should be noted that the present invention is not restricted to the above-described embodiments. The embodiments are merely examples so that any embodiments that have substantially the same feature and demonstrate the same functions and effects as those in the technical concept as disclosed in claims of the present invention are included in the technical range of the present invention.

### INDUSTRIAL APPLICABILITY

Employing a multivariate analysis in NMR for resist quality control makes it possible to discover a defect resist at an early stage without actually applying a resist to a substrate for an exposure evaluation test, and can contribute to the realization of efficient, quick, and simple quality control.

What is claimed is:

1. A resist quality control method comprising the steps of:
(1) pretreating a resist to obtain an analysis sample;
(2) subjecting the analysis sample to an instrumental analysis to obtain an analysis result;
(3) converting the analysis result into numerical data, followed by a multivariate analysis; and
(4) performing a quality control based on an analytical result thus obtained.

2. The resist quality control method according to claim 1, wherein the multivariate analysis is a principal component analysis.

3. The resist quality control method according to claim 1, wherein the instrumental analysis is a nuclear magnetic resonance analysis.

4. The resist quality control method according to claim 2, wherein the instrumental analysis is a nuclear magnetic resonance analysis.

5. The resist quality control method according to claim 1, wherein the pretreatment is dissolving the resist into a solvent.

6. The resist quality control method according to claim 2, wherein the pretreatment is dissolving the resist into a solvent.

7. The resist quality control method according to claim 3, wherein the pretreatment is dissolving the resist into a solvent.

8. The resist quality control method according to claim 4, wherein the pretreatment is dissolving the resist into a solvent.

9. The resist quality control method according to claim 1, wherein a peak derived from any one of a resist polymer, an acid generator, and a basic compound, which is included in the analysis result, is used as an indicator.

10. The resist quality control method according to claim 2, wherein a peak derived from any one of a resist polymer, an acid generator, and a basic compound, which is included in the analysis result, is used as an indicator.

11. The resist quality control method according to claim 3, wherein a peak derived from any one of a resist polymer, an acid generator, and a basic compound, which is included in the analysis result, is used as an indicator.

12. The resist quality control method according to claim 4, wherein a peak derived from any one of a resist polymer, an acid generator, and a basic compound, which is included in the analysis result, is used as an indicator.

13. The resist quality control method according to claim 5, wherein a peak derived from any one of a resist polymer, an acid generator, and a basic compound, which is included in the analysis result, is used as an indicator.

14. The resist quality control method according to claim 6, wherein a peak derived from any one of a resist polymer, an acid generator, and a basic compound, which is included in the analysis result, is used as an indicator.

15. The resist quality control method according to claim 7, wherein a peak derived from any one of a resist polymer, an acid generator, and a basic compound, which is included in the analysis result, is used as an indicator.

16. The resist quality control method according to claim 8, wherein a peak derived from any one of a resist polymer, an acid generator, and a basic compound, which is included in the analysis result, is used as an indicator.

17. A method for obtaining a resist quality prediction model, comprising the steps of:
(1) pretreating a plurality of resists whose qualities are known to obtain individual analysis samples;
(2) subjecting the individual analysis samples to an instrumental analysis to obtain individual analysis results; and
(3) converting a relation between the individual analysis results and the qualities into numerical data, followed by a multivariate analysis.

18. A resist quality control method comprising the steps of:
(1) pretreating a resist to obtain an analysis sample;
(2) subjecting the analysis sample to an instrumental analysis to obtain an analysis result;
(3) converting the analysis result into numerical data, followed by a multivariate analysis; and
(4) checking an analytical result thus obtained with a quality prediction model obtained according to claim 17.
